(19) United States
(12) Patent Application Publication
(10) Pub. No.: US 2004/0008035 A1
(43) Pub. Date: Jan. 15, 2004

(54) Proximity sensing device

(76) Inventor: Dennis J. Hickey, Preston (GB)

Correspondence Address: NIXON & VANDERHYE, PC, 1100 N GLEBE ROAD, 8TH FLOOR, ARLINGTON, VA, 22201-4714, US

(21) Appl. No.: 10/332,147

(22) PCT Filed: Jun. 29, 2001
(86) PCT No.: PCT/GB01/02914

(30) Foreign Application Priority Data
Jul. 5, 2000 (GB) 0016409.5

(51) Int. Cl. G01R 27/04; G01R 27/32

(52) U.S. Cl. 324/637

(57) ABSTRACT

A proximity sensing device comprising an antenna unit having a substantially longitudinal antenna extending therefrom, the antenna being encased along a substantial part of its length between an interior encasement portion and an exterior encasement portion, said encasement portions being configured so as to substantially immobilize the antenna, and the exterior encasement portion being adapted to permit the transmission of electro-magnetic radiation therethrough. The proximity sensing device is particularly suitable for use within the fuze of a projectile. The proximity sensing device advantageously has a dipole antenna.

This invention relates to the field of proximity sensing devices, and in particular to antenna units used in such devices. The invention is particularly, but not exclusively, concerned with proximity sensing devices incorporated on a projectile, for example within the fuze of an artillery shell or a mortar.

Proximity sensing devices located within projectiles are, in use, subject to strong sudden forces, particularly on launch. It is vital that these devices are not damaged before the detonation or impact of the projectile.

On launch, the fuze of a projectile is subject to vibration which can affect its components. The fuze generally comprises several units, for example it may comprise a micro-processor, a power pack, a safety and arming unit, and a detonator. A proximity fuze will also comprise a proximity sensing device. The vibrations which occur during launch can cause these components to strike each other and thereby suffer possible damage. To prevent excessive movement of these components, it is known to provide a packing material, such as a self expanding foam, within the fuze prior to launch. Polyurethane foam is often used, as this further acts to seal the fuze from the outside environment.

Proximity sensing devices are particularly sensitive to vibration, and vibration of the antenna of such a device can cause a projectile to detonate prematurely. It is therefore desirable to tightly pack the proximity sensing device in the fuze, however, whilst the antenna unit is generally unaffected by the packing foam, the antenna itself does not tend to function satisfactorily when the foam is present.

The present invention seeks to provide a proximity sensing device which is robust whilst seeking to overcome the problems described above.

According to the present invention there is provided a proximity sensing device comprising an antenna unit having a substantially longitudinal antenna extending therefrom, the antenna being encased along a substantial part of its length between an interior encasement portion and an exterior casement portion, said encasement portions being configured so as to substantially immobilise the antenna, and the exterior encasement portion being adapted to permit the transmission of electromagnetic radiation therethrough.

The exterior encasement portion advantageously is adapted to permit the transmission of microwave energy therethrough. Preferably the exterior encasement portion has a dielectric constant of 3.5 or less at 1 kHz. The exterior encasement portion may comprise a transparent polycarbonate.

Advantageously at least one of the exterior encasement portion and the interior encasement portion is rigid. Preferably both the exterior encasement portion and the interior encasement portion are rigid.

The antenna may comprise two dipoles. Each of the dipoles is advantageously encased along a substantial part of its length between an interior encasement portion and an exterior encasement portion. The encasement portions advantageously act to prevent any substantial vibration of the antenna.

The proximity sensing device may be incorporated within a fuze for a projectile. The encasement portions may comprise part of the body of the fuze. Advantageously the interior of the fuze is provided with a packing material which may also seal the fuze interior from the outside environment. Self-expanding polyurethane foam may be used for this purpose. The antenna is advantageously separated from the packing material by the interior encasement portion. The antenna unit is preferably located within the interior encasement portion, such that it is substantially protected by the packing material.

An embodiment of the present invention will now be described by way of example only and with reference to the following drawings of which:

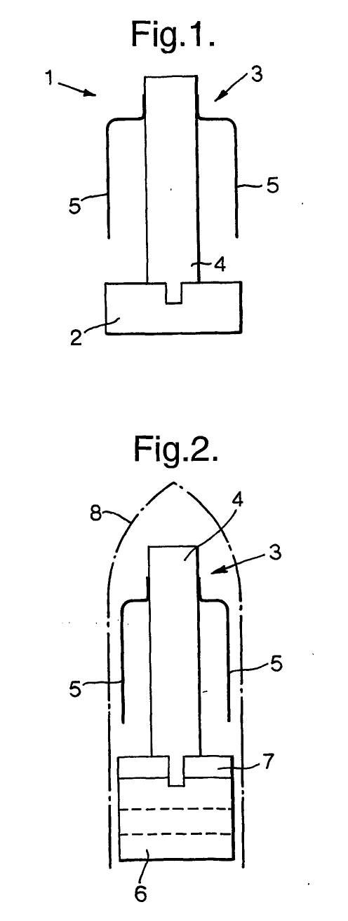

FIG. 1 shows a side view of a proximity sensing device.

FIG. 2 shows a side view of the device of FIG. 1 incorporated within a fuze.

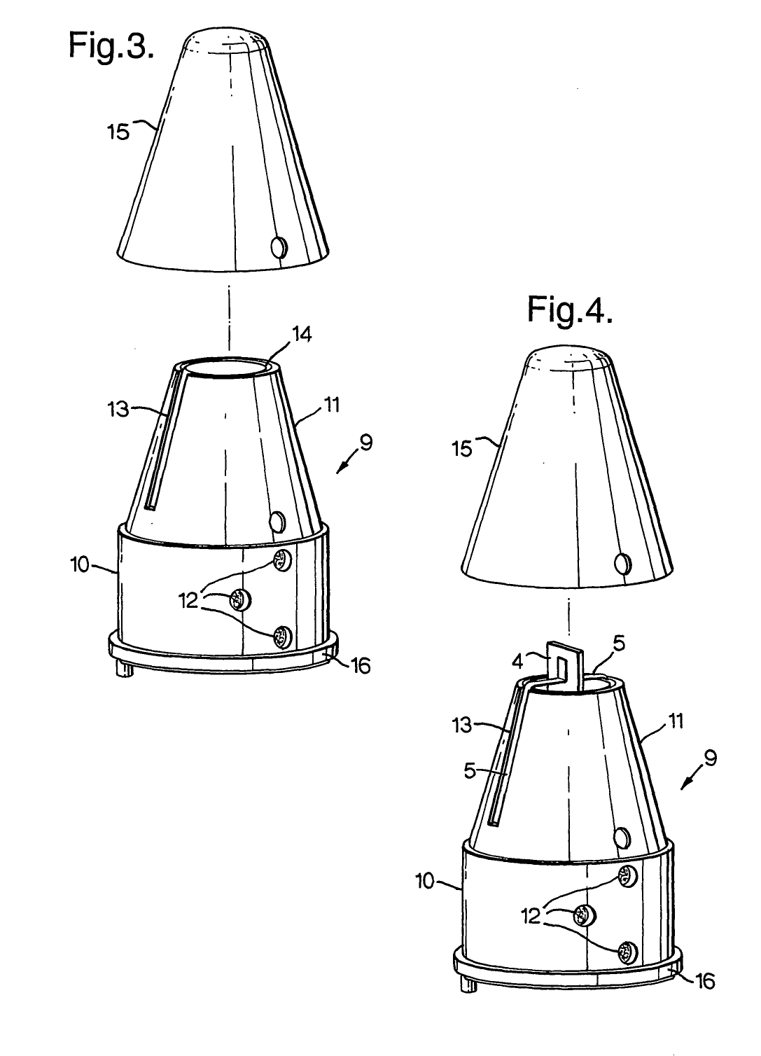

FIG. 3 shows an isometric view of the wall structure of a portion of the fuze of FIG. 2.

FIG. 4 shows an isometric view of the wall structure of FIG. 3 when the fuze is partly assembled.

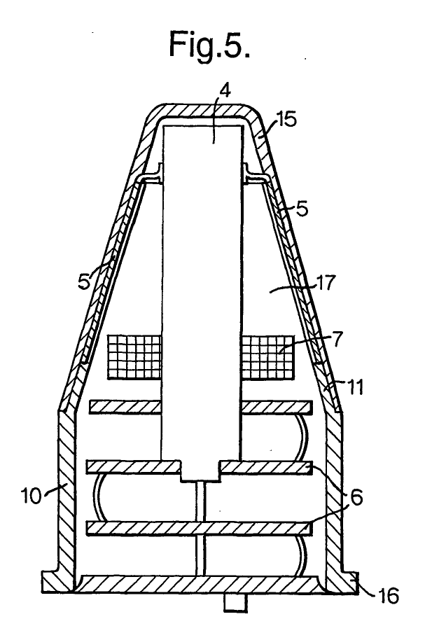

FIG. 5 shows a cross-sectional view of a forward portion of an assembled fuze incorporating the wall structure of FIGS. 3 and 4.

FIG. 1 shows a proximity sensing device 1 having an antenna system 3. The antenna system 3 comprises an antenna unit 4 with an antenna 5 extending therefrom. The antenna unit 4 comprises a circuit board that is in electrical contact with a processing unit 2.

FIG. 2 shows part of a fuze of a projectile incorporating a proximity sensing device 1. The outer wall of the fuze is represented by dotted line 8. The fuze has a series of circuit boards 6, to which the antenna circuit board 4 is connected. The circuit boards 6 incorporate the processor 2 shown in FIG. 1. The fuze further comprises a coil 7 for allowing inductive setting of the fuze.

FIG. 3 shows the wall structure of the part of the fuze shown in FIG. 2 in more detail. The fuze has a wall 9 comprising a lower wall 10 and an upper wall 11. The upper wall 11 has two grooves 13 for receiving a dipole antenna, the grooves 13 being located diametrically opposite each other. The wall 9 further comprises a frusto-conical insert 14 which separates the grooves 13 from the interior of the fuze. The lower wall 10 has a plurality of holes 12 for allowing a foam packing material to be injected into the fuze interior. The base 16 of the wall 9 is adapted to connect a further wall part of the fuze, in a known manner. The fuze also has a nose cover 15 for fitting over the upper wall 11. The grooves 13 may be adapted to extend only partially into the upper wall 11, such that a thin portion of the upper wall separates a dipole located in the groove 13 from the interior of the fuze. In this case no insert 14 is required. The lower wall 10 and upper wall 11 may be formed as a single item or alternatively be two separate items connected together.

FIG. 4 shows a partly assembled fuze having a fuze wall 9. An antenna circuit board 4 is connected to the circuit boards 6 (not shown) which are surrounded by lower wall 10. A dipole antenna 5 is attached to antenna circuit board 4, and the dipole antenna is fitted into grooves 13 which extend partly into the upper wall 11. The dipole antenna 5 is separated from the interior of the fuze by the thin remaining portion of the upper wall 11. The antenna circuit board 4 is located within the fuze body, surrounded by the upper wall 11. The nose cover 15 is placed over the upper wall 11, and fixed in position by known means such as gluing. The nose cover 15 protects the dipole antenna and the fuze interior from the outside environment. Polyurethane foam is injected into the fuze interior via holes 12 prior to launch to tightly pack the components inside the fuze and to seal the fuze interior from the outside environment. In this embodiment, the nose cover 15 acts as the exterior casement portion, and the upper wall portion 11 of the fuze wall 9 acts as the interior encasement portion. Where there is an insert, the upper wall portion 11 and the insert 14 of the fuze wall 9 act as the interior casement portion.

The fuze wall 9, and in particular its upper wall 11 and insert 14 components, is preferably made from a rigid plastic, glass or ceramic material which does not affect the operation of the antenna. The nose cover 15 is preferably made from a rigid material having a low dielectric constant, which is transparent to electromagnetic radiation and particularly to microwave energy. A clear polycarbonate is suitable for this purpose.

FIG. 5 shows an assembled front portion of a fuze. The dipole antenna 5 is located in the groove 13 of the upper wall 11 and is firmly held in position by the upper wall 11 and the nose cover 15. Polyurethane foam 17 has been injected into the fuze, substantially filling the fuze cavity shown, to tightly pack the components inside the fuze to prevent them from moving and becoming damaged.

Further embodiments of this invention may now suggest themselves to the skilled person, without departing from the scope of this invention.

1. A proximity sensing device comprising an antenna unit having a substantially longitudinal antenna extending therefrom, the antenna being encased along a substantial part of its length between an interior encasement portion and an exterior encasement portion, said encasement portions being configured so as to substantially immobilise the antenna, and the exterior encasement portion being adapted to permit the transmission of electromagnetic radiation therethrough.

2. A proximity sensing device as claimed in claim 1 wherein the exterior encasement portion is adapted to permit the transmission of microwave energy therethrough.

3. A proximity sensing device as claimed in claim 1 or claim 2 wherein the exterior encasement portion has a dielectric constant of 3.5 or less at 1 kHz.

4. A proximity sensing device as claimed in any preceding claim wherein the exterior encasement portion comprises a transparent polycarbonate.

5. A promixity sensing device as claimed in any preceding claim wherein at least one of the exterior encasement portion and the interior encasement portion is rigid.

6. A proximity sensing device as claimed in any preceding claim wherein both the exterior encasement portion and the interior encasement portion are rigid.

7. A proximity sensing device as claimed in any preceding claim wherein the antenna comprises two dipoles.

8. A proximity sensing device as claimed in claim 7 wherein each of said dipoles is encased along a substantial part of its length between an interior encasement portion and an exterior encasement portion.

9. A proximity sensing device substantially as hereinbefore described and with reference to the accompanying drawings.

10. A fuze comprising a proximity sensing device according to any one of claims 1 to 9.

11. A fuze as claimed in claim 10 wherein said encasement portions comprise part of the body of the fuze.

12. A fuze as claimed in claim 10 or claim 11 wherein the interior of the fuze contains a packing material, the antenna being separated from the packing material by the interior encasement portion.

13. A fuze as claimed in claim 12 wherein the antenna unit is located within the interior encasement portion such that it is substantially protected by the packing material.

14. A fuze substantially as hereinbefore described and with reference to the accompanying drawings.
